(19) United States
(12) Patent Application Publication
(10) Pub. No.: US 2026/0344110 A1
(43) Pub. Date: Oct. 29, 2026

(54) PHOTOVOLTAIC MODULE AND MANUFACTURING METHOD THEREOF

(71) Applicants: JINKO SOLAR CO., LTD., Jiangxi (CN); JINKO SOLAR (HAINING) CO., LTD., Haining City (CN)

(72) Inventors: Luchuang WANG, Jiangxi (CN); Wusong TAO, Jiangxi (CN); Yingying PENG, Jiangxi (CN); Yongqiao SONG, Jiangxi (CN)

(21) Appl. No.: 19/705,382

(22) Filed: Jun. 11, 2026

Related U.S. Application Data
(63) Continuation of application No. PCT/CN2026/087622, filed on Mar. 31, 2026.

(30) Foreign Application Priority Data
Apr. 25, 2025 (CN) 202510534200.3

(51) Int. Cl. H10F 77/00; H10F 19/80; H10F 19/90

(52) U.S. Cl. CPC H10F 77/937; H10F 19/804; H10F 19/908

(57) ABSTRACT

A photovoltaic module and a manufacturing method thereof are provided. The photovoltaic module includes at least two first cell strings arranged along a second direction. Each respective cell string of the first cell strings includes back-contact cells arranged sequentially along a first direction, and further includes first ribbons, at least one first covering film, second ribbons, second covering films and first wiring members. Each first ribbon extends along the first direction and has two ends respectively disposed on two adjacent back-contact cells. Each first covering film covers a surface of at least one intermediate cell of the intermediate cells. The second ribbons are arranged on at least one of the end cells. Each First wiring member is disposed on a respective intermediate cell adjacent to a corresponding end cell, and on a side of the at least one first covering film away from the back-contact cells.

### CROSS REFERENCE TO RELATED DISCLOSURES

The present disclosure is a continuation of PCT Patent Application No. PCT/CN2026/087622, entitled “PHOTOVOLTAIC MODULE AND MANUFACTURING METHOD OF THE SAME,” filed on Mar. 31, 2026, which claims priority to Chinese Patent Application No. 202510534200.3, entitled “PHOTOVOLTAIC MODULE AND MANUFACTURING METHOD THEREOF,” filed on Apr. 25, 2025, each of which is incorporated by reference herein in its entirety.

### TECHNICAL FIELD

The present disclosure relates to the field of photovoltaic technology, and more specifically to a photovoltaic module and a manufacturing method thereof.

### BACKGROUND

In photovoltaic technology, the most prominent feature of back contact (BC) cells is that both the PN junction (Positive Negative junction) and the contact metals are located on the back side of the BC cell. The front side of the BC cell completely avoids shading from metal grid electrodes, enabling maximum utilization of incident light, reducing optical losses, and delivering a higher short-circuit current. In photovoltaic modules, multiple back contact cell slices form cell strings through processes such as series soldering or full-panel module soldering, lamination, and encapsulation, with adjacent cell strings connected by wiring members.

In the soldering process of back-contact solar cells, since the grid lines of different polarities in back-contact solar cells are all located on the same surface, the corresponding solder ribbons need to be soldered to the same surface of the back-contact solar cells. After high-temperature soldering, back-contact solar cells are prone to warping, resulting in a decrease in the yield of photovoltaic modules. In addition, in the step of connecting wiring members, the wiring members are usually installed at the edges of back-contact solar cells. Therefore, a certain space needs to be reserved at the edges of back-contact solar cells to place the wiring members, and the reserved space reduces the light-receiving area of photovoltaic modules, leading to a decline in the efficiency of photovoltaic modules.

Therefore, how to improve the yield and efficiency of back-contact solar cell photovoltaic modules has become an urgent problem to be addressed.

### SUMMARY

A photovoltaic module and a manufacturing method thereof are provided, which are at least conducive to improving the efficiency and yield of the photovoltaic module.

In a first aspect, some embodiments of the present disclosure provide a photovoltaic module including a plurality of cell strings. At least two first adjacent cell strings of the plurality of cell strings are arranged along a second direction. Each respective cell string of the two first adjacent cell strings includes a plurality of back-contact cells arranged sequentially along a first direction, and further includes first ribbons, at least one first covering film, second ribbons, second covering films and first wiring members. The respective cell string includes end cells at opposite ends of the respective cell string, and intermediate cells between the end cells. A respective first ribbon of the first ribbons extends along the first direction and has two ends respectively disposed on two adjacent back-contact cells of the plurality of back-contact cells. A respective first covering film of the at least one first covering film covers a surface of at least one intermediate cell of the intermediate cells and embeds the first ribbons on the at least one intermediate cell. A respective first wiring member of the first wiring members is disposed on a respective intermediate cell of the intermediate cells adjacent to a corresponding end cell of the end cells, and on a side of the at least one first covering film away from the plurality of back-contact cells. The second ribbons are arranged on at least one of the end cells. At least a portion of the second ribbons is arranged on the corresponding end cell and has end portions extending beyond the corresponding end cell and is welded to the respective first wiring member. A respective second covering film of the second covering films is located on a side of the first ribbons and the portion of the second ribbons away from the corresponding end cell, and covers a surface of the corresponding end cell. A first end of a first wiring member of the first wiring members of one of the two first adjacent cell strings is electrically connected by welding to a second end of a first wiring member of the first wiring members of the other one of the two first adjacent cell strings.

In some embodiments, the respective first wiring member includes a first body portion and a first welding portion. In a direction perpendicular to the surface of the at least one intermediate cell, a thickness of the first welding portion is less than a thickness of the first body portion. The first welding portion is configured to weld and connect the respective first wiring member corresponding to one of the two first adjacent cell strings to the respective first wiring member corresponding to the other of the two first adjacent cell strings.

In some embodiments, the first welding portion of the respective first wiring member corresponding to one of the two first adjacent cell strings is welded to the first welding portion of the respective first wiring member corresponding to the other of the two first adjacent cell strings via the same connecting tab.

In some embodiments, the first welding portion of the respective first wiring member corresponding to one of the two first adjacent cell strings is directly welded to the first welding portion of the respective first wiring member corresponding to the other of the two first adjacent cell strings.

In some embodiments, at least two second adjacent cell strings of the plurality of cell strings are arranged along the first direction, and end cells of the two second adjacent cell strings that are not provided with the second ribbons are disposed adjacent to each other.

In some embodiments, the photovoltaic module further includes third ribbons and a second wiring member. A respective third ribbon of the third ribbons has two ends that are respectively disposed on a surface of a corresponding end cell of one of the two second adjacent cell strings and on a surface of a corresponding end cell of the other of the two second adjacent cell strings. The second wiring member is disposed on the respective intermediate cell adjacent to the corresponding end cell, and on a side of the at least one first covering film away from the plurality of back-contact cells. End portions of the third ribbons are welded to the same corresponding second wiring member.

In some embodiments, the respective second covering film is further located on a side of a respective third ribbon of the third ribbons away from the corresponding end cell.

In some embodiments, the photovoltaic module further includes an isolation film located between the first wiring members and the at least one first covering film.

In some embodiments, a surface of the isolation film facing the at least one first covering film is provided with an adhesive layer.

In some embodiments, a surface of the isolation film facing the first wiring members is provided with an adhesive layer.

In some embodiments, a melting point of the isolation film is higher than a melting point of the respective first covering film.

In some embodiments, the isolation film is further located between the second wiring members and the at least one first covering film.

In some embodiments, in a direction perpendicular to the surface of the at least one intermediate cell, a thickness of the respective first covering film is greater than a height of the respective first ribbon.

In some embodiments, in a direction perpendicular to the surface of the corresponding end cell, a thickness of the respective second covering film is greater than a height of the respective first ribbon.

In some embodiments, in a direction perpendicular to the surface of the corresponding end cell, a thickness of the respective second covering film is greater than the height of the respective second ribbon.

In some embodiments, the at least one first covering film is a single integrated first covering film and covers the surface of the at least one intermediate cell.

In some embodiments, a melting point of the respective first covering film is higher than a melting point of the respective second covering film.

In some embodiments, the respective intermediate cell is individually covered by the respective first covering film.

In some embodiments, a size of the respective second covering film is greater than or equal to a size of a respective back-contact cell of the plurality of back-contact cells, the size refers to dimension including the width along the first direction and the width along the second direction of both the respective second covering film and the respective back-contact cell.

In some embodiments, in the second direction, a width of the respective first covering film is greater than or equal to a width of a respective back-contact cell of the plurality of back-contact cells.

In a second aspect, some embodiments of the present disclosure provide a method for manufacturing a photovoltaic module, and the method includes:
preparing a plurality of cell strings, wherein the step of preparing the plurality of cell strings includes:
   providing a plurality of back-contact cells, and arranging the plurality of back-contact cells in sequence along a first direction, wherein two of the plurality of back-contact cells located at a first position and a last position in the respective cell string are end cells, and the others located between the end cells are intermediate cells;
   laying first ribbons such that two ends of each of the first ribbons are respectively located on surfaces of two adjacent back-contact cells along the first direction laying at least one first covering film such that the at least one first covering film is located on a side of the first ribbons away from the intermediate cells and covers surfaces of the intermediate cells;
   laying second ribbons and first wiring members such that the second ribbons are located on a surface of at least one of the end cells, the first wiring members are disposed on a respective intermediate cell of the intermediate cells adjacent to a corresponding end cell of the end cells and on a side of the at least one first covering film away from the plurality of back-contact cells, and ends of the second ribbons close to the respective intermediate cell are welded to the same first wiring member;
   laying second covering films such that the second covering films are located on a side of the first ribbons and the second ribbons away from the end cells and covers surfaces of the end cells; and
   connecting the plurality of cell strings, wherein at least two of the plurality of cell strings are arranged along a second direction and ends of the first wiring members of two adjacent cell strings along the second direction are electrically connected by welding.

In some embodiments, the method further includes:
before laying the second ribbons and the first wiring members, laying an isolation film on the at least one first covering film corresponding to the respective intermediate cell adjacent to one of the end cells, wherein the isolation film is located on a side of the at least one first covering film toward a corresponding end cell; and
the step of laying the second ribbons and the first wiring member includes:
   laying the first wiring member on the isolation film.

### BRIEF DESCRIPTION OF THE DRAWINGS

One or more embodiments are illustrated with reference to the accompanying drawings, and such exemplary description does not constitute a limitation on the embodiments. Unless otherwise stated, the figures in the accompanying drawings do not constitute a scale limitation. In order to more clearly illustrate technical solutions in the embodiments of the present disclosure or in the existing art, a brief description of the accompanying drawings used in the embodiments will be provided below. Obviously, the accompanying drawings in the following description illustrate only some embodiments of the present disclosure, and those of ordinary skill in the art may derive other drawings from these drawings without inventive effort.

FIG. 1 is a schematic structural diagram of a photovoltaic module according to some embodiments of the present disclosure.

FIG. 2 is a schematic cross-sectional structural view of FIG. 1 along the AA1 direction.

FIG. 3 is another schematic cross-sectional structural view of FIG. 1 along the AA1 direction.

FIG. 4 is a schematic structural diagram of another photovoltaic module according to some embodiments of the present disclosure.

FIG. 5 is a schematic view of a plurality of back-contact cells in a method for manufacturing a photovoltaic module according to some embodiments of the present disclosure.

FIG. 6 is a schematic view of after laying first ribbons in a method for manufacturing a photovoltaic module according to some embodiments of the present disclosure.

FIG. 7 is a schematic view of after laying first covering film in a method for manufacturing a photovoltaic module according to some embodiments of the present disclosure.

FIG. 8 is a schematic view of after laying second ribbons and first wiring members in a method for manufacturing a photovoltaic module according to some embodiments of the present disclosure.

FIG. 9 is a schematic view of after laying second covering films in a method for manufacturing a photovoltaic module according to some embodiments of the present disclosure.

### LIST OF REFERENCE NUMERAL

10 Cell string

100 Back-contact cell

101 End cell

102 Intermediate cell

111 First ribbon

112 Second ribbon

113 Third ribbon

121 First covering film

122 Second covering film

131 First wiring member

132 Second wiring member

1311 First welding portion

1312 First body portion

1313 Connecting tab.

### DETAILED DESCRIPTION OF THE EMBODIMENTS

As described in the background section, how to improve the yield and efficiency of back-contact solar cell modules has become an urgent problem to be addressed.

Embodiments of the present disclosure provide a photovoltaic module and a manufacturing method thereof, which are at least conducive to improving the efficiency and yield of the photovoltaic module.

In the description of the embodiments of the present disclosure, the technical terms such as “first,” “second,” and the like are merely used to distinguish one element from another and should not be construed as indicating or implying relative importance, or implying the number, specific sequence, or priority of the technical features being described.

In the description of the embodiments of the present disclosure, “a plurality of” means two or more, unless expressly specified otherwise.

Any reference to “embodiment(s)” herein means that particular features, structures, or characteristics described in combination with the embodiment(s) may be included in at least one embodiment of the present disclosure. A phrase appearing in various places in the specification does not necessarily refer to the same embodiment, nor is an independent or alternative embodiment mutually exclusive with other embodiments. It is explicitly and implicitly understood by those skilled in the art that the embodiments described herein may be combined with other embodiments.

In the description of the embodiments of the present disclosure, the term “and/or” represents merely an association relationship describing associated objects, indicating that there may be three types of relationships. For example, A and/or B, which means three possible cases, that is, the existence of A alone, the existence of both A and B, and the existence of B alone. In addition, the character “/” herein generally indicates that the associated objects are in an “or” relationship.

In the description of the embodiments of the present disclosure, the terms “center,” “longitudinal,” “transverse,” “length,” “width,” “thickness,” “upper,” “lower,” “front,” “rear,” “left,” “right,” “vertical,” “horizontal,” “top,” “bottom,” “inner,” “outer,” “clockwise,” “counterclockwise,” “axial,” “radial,” “circumferential,” and other indicated orientations or positional relationships are based on the orientation or positional relationships shown in the accompanying drawings, and are only for the convenience of describing the embodiments of the present disclosure and simplifying the description, rather than indicating or imply that indicated devices or elements must have a specific orientation, be constructed and operate in a particular orientation and are therefore not to be construed as limitations to the embodiments of the present disclosure.

In the description of the embodiments of the present disclosure, unless otherwise explicitly specified or defined, the technical terms “mounting,” “connecting,” “connection,” and “fixed” should be understood in a broad sense; for example, they may be a fixed connection, a detachable connection, or an integrated structure; may be a mechanical connection, or an electrical connection; and may be a direct connection or an indirect connection via an intermediate medium, or internal communication between two components or an interactive relationship between them. For those of ordinary skill in the art, specific meanings of the above terms in the embodiments of the present disclosure could be understood according to specific circumstances.

In the drawings corresponding the embodiments of the present disclosure, for better understanding and ease of illustration, thicknesses and sizes of the layers are enlarged. Throughout the specification, the same reference numerals denote the same elements. Furthermore, when a component is referred to as being “substantially formed on” another component, it means that the component is not formed over the entire surface (or front surface) of the other component, nor merely on a portion of an edge thereof.

In the description of the embodiments of the present disclosure, when a certain component is referred to as “including” another component, unless otherwise specified, it does not exclude the presence of other components, and such other components may also be included.

The terminology used in the description of the various embodiments herein is intended solely to describe specific embodiments and is not intended to be limiting. As used in the description of the various embodiments and in the appended claims, “the component” is also intended to include the plural form, unless the context clearly dictates otherwise.

The various embodiments of the present disclosure will be described in detail below with reference to the accompanying drawings. However, those skilled in the art should understand in each embodiment of the present disclosure, many technical details have been put forward in order to make readers better understand the present disclosure. Nevertheless, even without these technical details and various changes and modifications based on the embodiments below, technical solutions to be protected according to the embodiments of the present disclosure may be substantially implemented.

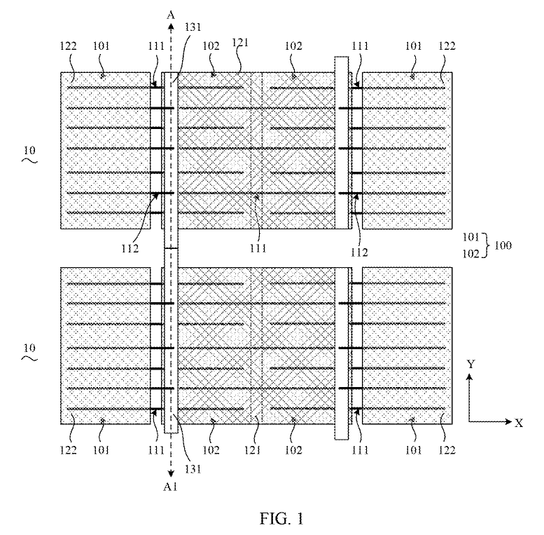

FIG. 1 is a schematic structural diagram of a photovoltaic module according to some embodiments of the present disclosure.

Referring to FIG. 1, embodiments of the present application provide a photovoltaic module including a plurality of cell strings 10. Each respective cell string 10 of the plurality of cell strings 10 includes a plurality of back-contact cells 100, first ribbons 111, at least one first covering film 121, second ribbons 112, second covering films 122, and first wiring members 131.

The plurality of back-contact cells 100 are arranged sequentially along a first direction X. The respective cell string includes end cells 101 at opposite ends of the respective cell string, and intermediate cells 102 between the end cells 101.

Each first ribbon 111 extends along the first direction X and has two ends that are respectively disposed on two adjacent back-contact cells 100 of the plurality of back-contact cells 100. Each first ribbon 111 is configured to connect the two adjacent back-contact cells 100. Specifically, one end of each first ribbon 111 is configured to connect either a positive grid line or a negative grid line of one of the two adjacent back-contact cells 100, and the other end is configured to connect the other of the positive grid line or the negative grid line of the other one of the two adjacent back-contact cells 100, thereby connecting the two adjacent back-contact cells 100 in series.

Each first covering film 121 is located on a side of the first ribbons 111 away from the intermediate cells 102 and covers a surface of at least one intermediate cell of the intermediate cells 102 and embeds the first ribbons 111 on the at least one intermediate cell 102. Each first covering film 121 is configured to fix the position of the first ribbons 111 on the at least one intermediate cell 102.

The second ribbons 112 are arranged on at least one of the end cells 101. Each second ribbon 112 is configured to be welded to a respective first wiring member 131, so as to lead current out from the two adjacent back-contact cells 100 to the respective first wiring member 131. At least a portion of the second ribbons 112 is arranged on the corresponding end cell 101 and has end portions extending beyond the corresponding end cell 101 and welded to the respective first wiring member 131.

Each second covering film 122 is located on a side of the first ribbons 111 and the portion of the second ribbons 112 away from corresponding end cell of the end cells 101, and covers a surface of the corresponding end cell 101. Each second covering film 122 is configured to fix the first ribbons 111 and the second ribbons 112 on the corresponding end cell.

The respective first wiring member 131 is disposed on a respective intermediate cell 102 of the intermediate cells adjacent to a corresponding end cell of the end cells 101 and on a side of the at least one first covering film 121 away from the plurality of back-contact cells 100.

At least two adjacent cell strings of the plurality of cell strings 10 are arranged along a second direction Y, and ends of the respective first wiring member 131 of the two adjacent cell strings 10 are electrically connected by welding.

In the photovoltaic module provided by the embodiments of the present disclosure, the two adjacent back-contact cells 100 are connected via the first ribbons 111 to form a cell string 10. Two end cells 101 located at the first position or the last position are configured to lead out current to the first wiring members 131 via the second ribbons 112. Each first covering film 121 is configured to fix the positions of the first ribbons 111 on the corresponding intermediate cell 102. Each second covering film 122 is configured to fix the positions of the first ribbons 111 and the second ribbons 112 on the corresponding end cell 101. This can avoid warpage of the plurality of back-contact cells 100 caused by high-temperature welding, thereby helping to improve the yield of the photovoltaic module. The respective first wiring member 131 is disposed on the respective intermediate cell 102 adjacent to the corresponding end cell 101, and on a side of the at least one first covering film 121 away from the plurality of back-contact cells 100. In this way, the at least one first covering film 121 can isolate the respective intermediate cell 102 from the first wiring members 131, so as to avoid current leakage between the first wiring members 131 and the ribbons of different polarities on the respective intermediate cell 102. At the same time, disposing the first wiring members 131 on the respective intermediate cell 102 helps to hide the first wiring members 131 on the back side of the plurality of back-contact cells 100, preventing the first wiring members 131 from occupying effective areas of the photovoltaic module, thereby contributing to an improvement in the photoelectric conversion efficiency of the photovoltaic module. Ends of the first wiring members 131 of the two adjacent cell strings 10 arranged along the second direction Y are electrically connected by welding. Thus, during the preparation of the plurality of cell strings 10, the first wiring members 131 may be pre-welded to the second ribbons 112. During the series connection of the plurality of cell strings 10, the series connection of the plurality of cell strings 10 can be realized simply by welding the first wiring members 131 of the two adjacent cell strings 10 along the second direction, thereby improving the manufacturing efficiency of the photovoltaic module.

In some embodiments, the plurality of back-contact cells 100 may be an IBC (Interdigitated Back Contact) cell, an HPBC (Hybrid Passivated Back Contact) cell, a TBC cell combining TOPCon (Tunnel Oxide Passivated Contact) cell technology and IBC technology, or an HBC cell combining HIT/HJT (Heterojunction Technology) cell technology and IBC technology; certainly, other types of back-contact cells may also be used.

In some embodiments, the first ribbons 111 and the second ribbons 112 may be low-temperature ribbons, i.e., ribbons with a melting point less than or equal to 175°C. In this way, the subsequent lamination process can be used to alloy the first ribbons 111 and the second ribbons 112 with the metal grid electrodes on the plurality of back-contact cells 100, thereby enabling a higher current transport efficiency between the first ribbons 111 and the second ribbons 112 and the plurality of back-contact cells 100.

FIG. 2 is a schematic cross-sectional structural view of FIG. 1 along the AA1 direction.

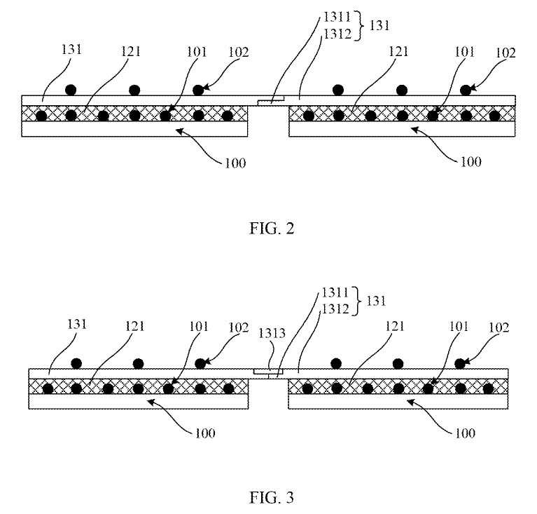

Referring to FIGS. 2 and 3, the respective first wiring member 131 may include a first body portion 1312 and a first welding portion 1311. The first welding portion 1311 is configured to weld and connect the respective first wiring member 131 corresponding to one of the two adjacent cell strings 10 to the respective first wiring member 131 corresponding to the other of the two adjacent cell strings 10.

Referring to FIG. 2, in some embodiments, the first welding portion 1311 of the respective first wiring member 131 corresponding to one of the two adjacent cell strings 10 is directly welded to the first welding portion 1311 of the respective first wiring member 131 corresponding to the other of the two adjacent cell strings 10. Alternatively, referring to FIG. 3, in other embodiments, the first welding portion 1311 of the respective first wiring member 131 corresponding to one of the two adjacent cell strings 10 is welded to the first welding portion 1311 of the respective first wiring member 131 corresponding to the other of the two adjacent cell strings 10 via the same connecting tab 1313, so as to achieve electrical connection.

Referring to FIGS. 2 and 3, in some embodiments, in a direction perpendicular to the surfaces of the plurality of back-contact cells 100, a thickness of the first welding portion 1311 is less than a thickness of the first body portion 1312. In this way, regardless of whether the first welding portion 1311 of the respective first wiring member 131 corresponding to one of the two adjacent cell strings 10 is directly welded or connected via the connecting tab 1313, a total thickness at the position corresponding to the first welding portion 1311 after welding may be less than or equal to a thickness of the first body portion 1312, thereby avoiding fragmentation of the plurality of back-contact cells 100 caused by stress concentration due to an excessively large thickness at the position corresponding to the first welding portion 1311 after welding.

In other embodiments, the thickness of the first welding portion 1311 may also be greater than or equal to the thickness of the first body portion 1312.

Referring to FIGS. 2 and 3, in the direction perpendicular to the surfaces of the plurality of back-contact cells 100, a thickness of the respective first covering film 121 may be greater than a height of the respective first ribbon 111. In this way, the at least one first covering film 121 may wrap the first ribbons 111, and a surface of the at least one first covering film 121 facing away from the first ribbons 111 may be relatively flat, which helps to increase the contact area between the first wiring members 131 and the at least one first covering film 121, avoiding excessive stress concentration points between the uneven surface of the at least one first covering film 121 and the first wiring members 131, and further avoiding fragmentation of the plurality of back-contact cells 100 caused by stress concentration.

Similarly, in the direction perpendicular to the surfaces of the plurality of back-contact cells 100, a thickness of the respective second covering film 122 may be greater than a height of the respective first ribbon 111; and/or, in the direction perpendicular to the surfaces of the plurality of back-contact cells, a thickness of the respective second covering film 122 may be greater than a height of the respective second ribbon 112, so that the respective second covering film 122 can wrap the first ribbons 111 and/or the second ribbons 112, and a surface of the respective second covering film 122 facing away from the plurality of back-contact cells 100 may be relatively flat.

In some embodiments, the thickness of the respective second covering film 122 may be greater than the thickness of the respective first covering film 121. In this way, a distance between the surface of the respective second covering film 122 facing away from the plurality of back-contact cells 100 and a surface of the plurality of back-contact cells 100 may be close to a distance between the surface of the respective first wiring member 131 facing away from the plurality of back-contact cells 100 and the surface of the plurality of back-contact cells 100. In other words, relative to the surface of the plurality of back-contact cells 100, a height difference between the respective second covering film 122 facing away from the plurality of back-contact cells 100 and the respective first wiring member 131 facing away from the plurality of back-contact cells 100 is reduced, thereby avoiding uneven filling of adhesive films caused by the height difference during a subsequent lamination process.

In some embodiments, a melting point of the respective first covering film 121 is higher than a melting point of the respective second covering film 122. The respective first covering film 121 is configured to isolate the first wiring members 131 from the respective intermediate cell 102. The relatively higher melting point of the at least one first covering film 121 prevents excessive melting of the at least one first covering film 121 during the subsequent lamination process, which would otherwise cause the first wiring members 131 to contact ribbons of different polarities on the respective intermediate cell 102 and result in current leakage.

In FIG. 1, a single integrated first covering film 121 covers the surface of the at least one intermediate cell 102. In this way, in the step of laying the at least one first covering film 121, after the first ribbons 111 are laid on the at least one intermediate cell 102, the single integrated first covering film 121 may be used to cover the at least one intermediate cell 102. On the one hand, the laying efficiency of the at least one first covering film 121 is improved; on the other hand, the at least one first covering film 121 can assist in fixing the relative position of the at least one intermediate cell 102, thereby avoiding defects in the at least one intermediate cell 102 caused by pulling of the at least one intermediate cell 102 by the first ribbons 111 in subsequent process steps.

In other embodiments, the respective intermediate cell 102 may be individually covered by the respective first covering film 121.

In FIG. 1, in the second direction Y, the width of the respective first covering film 121 is illustrated as being equal to the width of each back-contact cell 100 for exemplary purposes only, which does not limit the size of the respective second covering film 122. In other embodiments, in the second direction Y, the width of the respective first covering film 121 may be greater than the width of each back-contact cell 100, so as to lower alignment accuracy requirements for the at least one first covering film 121 and improve its laying efficiency. When the respective intermediate cell 102 is individually covered by the respective first covering film 121, the size of the respective first covering film 121 may be greater than the size of each back-contact cell 100, where the size includes the width along the first direction and/or the width along the second direction.

Similarly, in FIG. 1, in the second direction Y, the size of the respective second covering film 122 is illustrated as being equal to the size of each back-contact cell 100 for exemplary purposes only. The size refers to dimension including the width along the first direction X and the width along the second direction Y of the respective second covering film 122, which does not limit the size of the respective second covering film 122. In other embodiments, the size of the respective second covering film 122 may also be greater than the size of each back-contact cell 100 to improve the laying efficiency of the respective second covering film 122.

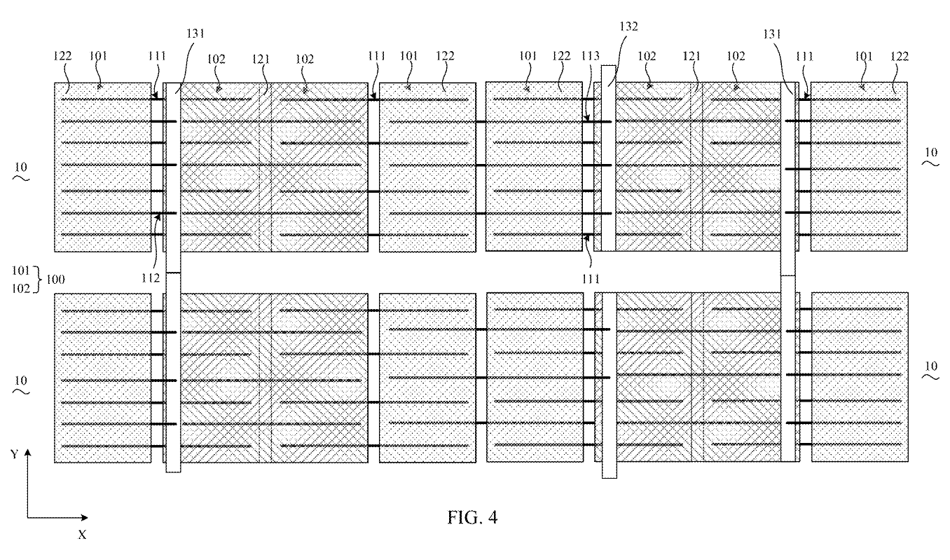

FIG. 4 is a schematic structural diagram of another photovoltaic module according to some embodiments of the present disclosure.

Referring to FIG. 4, in some embodiments, at least two cell strings 10 of the plurality of cell strings are arranged along the first direction X, and end cells 101 of the two adjacent cell strings 10 that are not provided with the second ribbons 112, of the two adjacent cell strings 10, are disposed adjacent to each other. The photovoltaic module may further include third ribbons 113 and a second wiring member 132. Each third ribbon 113 has two ends that are respectively disposed on a surface of a corresponding end cell 101 of one of the two adjacent cell strings 10 and on a surface of a corresponding end cell 101 of the other of the two adjacent cell strings 10. The second wiring member 132 is disposed on the respective intermediate cell 102 adjacent to the corresponding end cell 101, and on a side of the at least one first covering film 121 away from the plurality of back-contact cells 100. End portions of the third ribbons 113 are welded to the same corresponding second wiring member 132. The respective second covering film 122 is further located on a side of the third ribbons 113 away from the corresponding end cell 101, and covers surface of the corresponding end cell 101. That is, the two adjacent cell strings 10 along the first direction X are arranged in parallel via the second wiring member 132, and the two adjacent cell strings 10 along the second direction Y are connected in series after being welded together via the corresponding first wiring member 131.

After the two adjacent cell strings 10 are connected in parallel via the third ribbons 113, the current on the third ribbons 113 is lead out via the second wiring member 132. The second wiring member 132 is located on a side of the respective first covering film 121 away from the plurality of back-contact cells 100. In this way, the at least one first covering film 121 can be used to isolate the intermediate cells 102 from the second wiring member 132, so as to avoid current leakage between the second wiring member 132 and ribbons of different polarities on the at least one intermediate cell 102. Meanwhile, the second wiring member 132 is disposed on the corresponding intermediate cell 102, which facilitates hiding the second wiring member 132 on the back side of the plurality of back-contact cells 100 and prevents the second wiring member 132 from occupying an effective area of the photovoltaic module, thereby helping improve the photoelectric conversion efficiency of the photovoltaic module.

In some embodiments, the second wiring member 132 includes a second body portion (not shown in the figures) and a second welding portion (not shown in the figures). The second welding portion is configured to weld and connect the second wiring member 132 corresponding to one of the two adjacent cell strings 10 to the second wiring member 132 corresponding to the other of the two adjacent cell strings 10. Two second welding portions of the second wiring member 132 corresponding to the two adjacent cell strings 10 may be directly welded to each other, or welded to the same connecting tab 1313 to achieve electrical connection. In a direction perpendicular to the surface of the plurality of back-contact cells, the thickness of the second welding portion is less than the thickness of the second body portion. In this way, the total thickness at a position corresponding to the second welding portion after welding may be less than or equal to the thickness of the second body portion, thereby avoiding fragmentation of the plurality of back-contact cells caused by stress concentration due to an excessively large thickness at the position corresponding to the second welding portion after welding.

In some embodiments, the photovoltaic module may further include an isolation film (not shown in the figures). The isolation film is located between the first wiring members 131 and the at least one first covering film 121. The isolation film can further improve the isolation effect between the first wiring members 131 and the intermediate cells 102, so as to avoid current leakage between the first wiring members 131 and the intermediate cells 102.

In some embodiments, the isolation film may also be located between the second wiring member 132 and the at least one first covering film 121, so as to further improve the insulation between the second wiring member 132 and the intermediate cells 102, so as to avoid current leakage between the second wiring member 132 and the intermediate cells 102.

When the isolation film is located between the first wiring members 131 and the at least one first covering film 121, a surface of the isolation film facing the at least one first covering film 121 is provided with an adhesive layer, and/or a surface of the isolation film facing the first wiring members 131 is provided with an adhesive layer. When the isolation film is located between the second ribbons 112 and the second covering films 122, a surface of the isolation film facing the at least one first covering film 121 is provided with an adhesive layer, and/or a surface of the isolation film facing the second wiring member 132 is provided with an adhesive layer. The adhesive layer on the surface of the isolation film facing the at least one first covering film 121 or the second covering films 122 may help fix the relative position between the isolation film and the corresponding covering film. The adhesive layer on the surface of the isolation film facing the first wiring members 131 or the second wiring member 132 may help fix the relative position between the isolation film and the corresponding wiring member, thereby improving the laying stability of the isolation film.

In some embodiments, a melting point of the isolation film is higher than a melting point of the respective first covering film 121. In this way, the isolation effect between the first wiring members 131 and/or the second wiring member 132 and the at least one intermediate cell 102 can be improved, so as to avoid current leakage caused by contact between the first wiring members 131 and/or the second wiring member 132 and ribbons of different polarities on the at least one intermediate cell 102 due to excessive melting of the at least one first covering film 121 during the lamination process.

It should be noted that, in FIGS. 1 and 4, the number of the plurality of the back-contact cells 100 in the respective cell string 10 is illustrated as four for exemplary purposes only, which does not limit the number of the plurality of the back-contact cells 100 in the respective cell string 10. In other embodiments, the number of back-contact cells in the respective cell string 10 may be 3, 5, 7, or 10, etc.

In the photovoltaic module provided by the embodiments of the present disclosure, the two adjacent back-contact cells 100 are connected via the first ribbons 111 to form a cell string 10. Two end cells 101 located at the first position or the last position are configured to lead out current to the first wiring members 131 via the second ribbons 112. The respective first covering film 121 is configured to fix the positions of the first ribbons 111 on the corresponding intermediate cell 102. The respective second covering films 122 is configured to fix the positions of the first ribbons 111 and the second ribbons 112 on the corresponding end cell 101. This can avoid warpage of the plurality of back-contact cells 100 caused by high-temperature welding, thereby helping to improve the yield of the photovoltaic module. The respective first wiring member 131 is disposed on the respective intermediate cells 102 adjacent to the corresponding end cell 101, and on a side of the at least one first covering film 121 away from the plurality of back-contact cells 100. Thus, the at least one first covering film 121 can isolate the respective intermediate cell 102 from the first wiring members 131, so as to avoid current leakage between the first wiring members 131 and the ribbons of different polarities on the intermediate cells 102. Meanwhile, disposing the first wiring members 131 on the respective intermediate cell 102 helps to hide the first wiring members 131 on the back side of the plurality of back-contact cells 100, preventing the first wiring members 131 from occupying effective areas of the photovoltaic module, thereby contributing to an improvement in the photoelectric conversion efficiency of the photovoltaic module. Ends of the first wiring members 131 of the two adjacent cell strings 10 arranged along the second direction Y are electrically connected by welding. Thus, during preparation of the plurality of cell strings 10, the first wiring members 131 may be pre-welded to the second ribbons 112. During the series connection of the plurality of cell strings 10, the series connection of the plurality of cell strings 10 can be realized simply by welding the first wiring members 131 of the two adjacent cell strings 10 along the second direction, thereby improving the manufacturing efficiency of the photovoltaic module.

Accordingly, another embodiment of the present disclosure further provides a method for manufacturing a photovoltaic module, which may be used to manufacture the photovoltaic module provided in the aforementioned embodiments. For parts identical or corresponding to those in the previous embodiments, reference may be made to the corresponding descriptions of the foregoing embodiments, and detailed descriptions thereof will be omitted hereinafter.

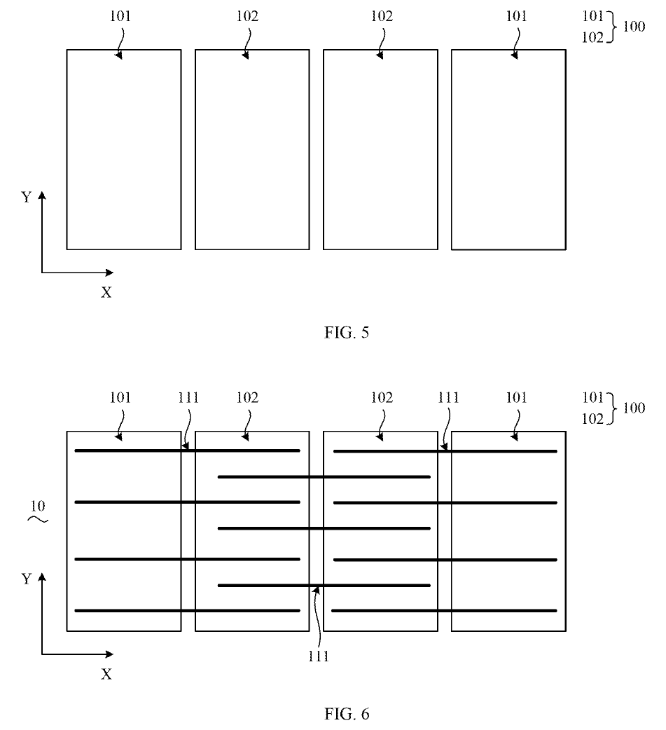

FIGS. 5-9 are schematic views corresponding to various steps of a method for manufacturing a photovoltaic module according to some embodiments of the present disclosure.

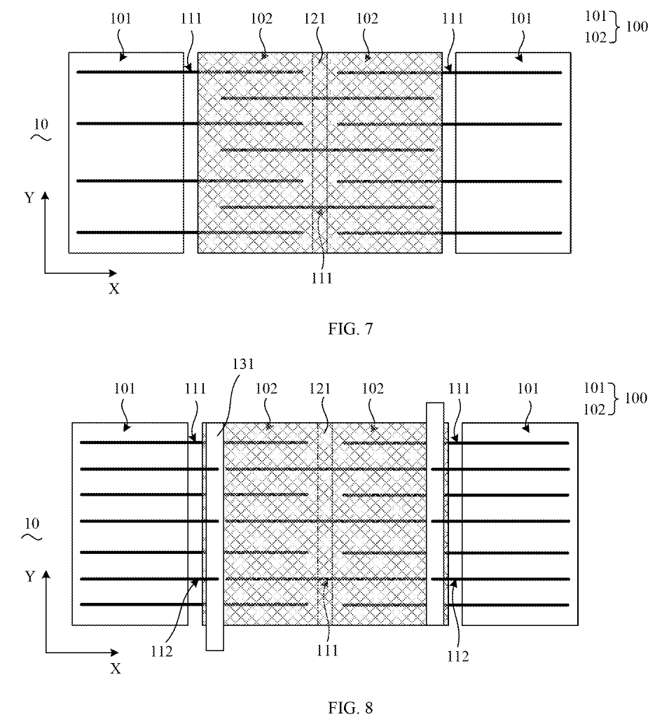

Referring to FIGS. 5-9, another aspect of the embodiments of the present disclosure further provides a method for manufacturing a photovoltaic module, the method includes the following steps.
S11, a plurality of cell strings 10 are provided, where the step of preparing the plurality of cell strings 10 includes:
S21, referring to FIG. 5, a plurality of back-contact cells 100 are provided, and the plurality of back-contact cells 100 are arranged sequentially along a first direction X. Two of the plurality of back-contact cells 100 arranged at a first position and a last position are end cells 101, and the others 100 located between the end cells 101 are intermediate cells 102.
S22, referring to FIG. 6, first ribbons 111 are laid, such that two ends of each of the first ribbons 111 are respectively located on surfaces of two adjacent back-contact cells 100 along the first direction X.
S23, referring to FIG. 7, at least one first covering film 121 are laid, such that the at least one first covering film 121 is located on a side of the first ribbons 111 away from the intermediate cells 102 and covers surfaces of the intermediate cells 102.

In FIG. 7, a single piece of the at least one first covering film 121 is used as an example to cover the intermediate cells 102. On one hand, it helps improve the laying efficiency of the at least one first covering film 121; on the other hand, the at least one first covering film 121 can assist in fixing the relative positions among the intermediate cells 102, thereby avoiding defects of the intermediate cells 102 caused by the pulling of the intermediate cells 102 by the first ribbons 111 in subsequent process steps. In other embodiments, each of the intermediate cells 102 may be separately covered with a respective one of the at least one first covering film.

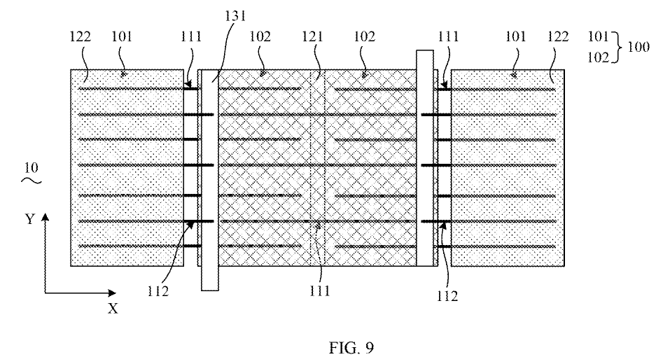

S24, referring to FIG. 8, second ribbons 112 and first wiring members 131 are laid, such that the second ribbons 112 are located on a surface of at least one of the end cells 101, the first wiring members 131 are disposed on a respective intermediate cell 102 of the intermediate cells 102 adjacent to a corresponding end cell of the end cells 101 and on a side of the at least one first covering film 121 away from the plurality of back contact cells 100. Ends of the second ribbons 112 close to the respective intermediate cell 102 are welded to the same first wiring member 131.

In some embodiments, the method further includes before laying the second ribbons 112 and the first wiring members 131, laying an isolation film (not shown in the figures) on the at least one first covering film 121 corresponding to the respective intermediate cell 102 adjacent to one of the end cells 101, where the isolation film is located on a side of the at least one first covering film 121 toward a corresponding end cell of the end cells 101. The step of laying the second ribbons 112 and the first wiring members 131 includes laying the first wiring members 131 on the isolation film. The isolation film can further improve the isolation effect between the first wiring members 131 and the intermediate cells 102, so as to avoid current leakage between the first wiring members 131 and the intermediate cells 102.

Before laying the second ribbons 112 and the first wiring members 131, the second ribbons 112 and the first wiring members 131 may have been welded into an assembly so as to help improve the manufacturing efficiency of the photovoltaic module.

S25, referring to FIG. 9, laying second covering films 122 such that the second covering films 122 are located on a side of the first ribbons 111 and the second ribbons 112 away from the end cells 101 and cover surfaces of the end cells 101.

S12, referring to FIG. 1, connecting the plurality of cell strings 10, where at least two of the plurality of cell strings 10 are arranged along a second direction Y, and ends of the first wiring members 131 corresponding to two adjacent cell strings 10 along the second direction are electrically connected by welding.

Referring back to FIG. 2, in some embodiments, the first wiring members 131 corresponding to the two adjacent cell strings 10 may be directly welded to each other. Alternatively, referring back to FIG. 3, in other embodiments, the first wiring members 131 corresponding to the two adjacent cell strings 10 are both welded to the same connecting tab 1313, so as to achieve electrical connection.

Referring back to FIG. 4, in some embodiments, in step S24, a second wiring member 132 and third ribbons 113 are laid simultaneously with the first wiring members 131 and the second ribbons 112. Specifically, the two adjacent cell strings 10 are arranged along the second direction Y. The second ribbons 112 are laid on the end cells 101 located at two ends along the second direction Y, and the third ribbons 113 are laid on the two adjacent end cells 101. One end of the third ribbon 113 is located on a surface of the corresponding end cell of the end cells 101 of one cell string 10, and the other end of the third ribbon 113 is located on a surface of the corresponding end cell of the end cells 101 of the other cell string 10. The second wiring member 132 is disposed on the respective intermediate cell 102 adjacent to a corresponding end cell of the end cells 101, and located on a side of the at least one first covering film 121 away from the plurality of back-contact cells 100. All ends of the third ribbons 113 are welded to the same second wiring member 132. Furthermore, in step 25, during laying of the second covering films 122, the second covering films 122 are further located on a side of the third ribbons 113 away from the end cells 101 and covers surfaces of the end cells 101. In S12, when connecting the plurality of cell strings 10, two adjacent cell strings 10 along the first direction X are arranged in parallel via the second wiring member 132, and the two adjacent cell strings 10 along the second direction Y are connected in series after being welded via the first wiring members 131.

After connecting the plurality of cell strings 10 in S12, the method may further include:
laying a first cover plate and a first encapsulation layer;
disposing the connected cell strings on the first encapsulation layer;
laying a second encapsulation layer and a second cover plate on the connected cell strings; and performing a lamination process to obtain a photovoltaic module.

A material of the first encapsulation layer and a material of the second encapsulation layer may each be an organic encapsulation film, such as an ethylene-vinyl acetate (EVA) film, a polyethylene octene elastomer (POE) film, or a polyvinyl butyral (PVB) film.

Each of the first cover plate and the second cover plate may be a cover plate with a light-transmitting function, such as a glass cover plate or plastic cover plate.

In the method for manufacturing a photovoltaic module provided by the embodiments of the present disclosure, after the plurality of back-contact cells 100 are arranged, the first ribbons 111 and the at least one first covering film 121 are laid first, and the plurality of back-contact cells 100 are connected in series via the first ribbons 111. The plurality of back-contact cells 100 located at the first position and the last position are end cells 101, and the others 100 located between the end cells 101 are intermediate cells 102. The at least one first covering film 121 is configured to fix positions of the first ribbons 111 on the intermediate cells 102, and further configured to isolate the intermediate cells 102 from the first wiring members 131 in subsequent process steps, so as to avoid current leakage between the first wiring members 131 and ribbons of different polarities on the intermediate cells 102. Subsequently, the second ribbons 112, the second wiring member 132, and the second covering film 122 are laid on the end cells 101. The end cells 101 lead out current to the first wiring members 131 via the second ribbons 112. The first wiring members 131 are disposed on the intermediate cells 102, which facilitates hiding the first wiring members 131 on the back side of the plurality of back-contact cells 100, preventing the first wiring members 131 from occupying effective areas of the photovoltaic module, thereby helping improve the photoelectric conversion efficiency of the photovoltaic module. The second covering film 122 is configured to fix positions of the first ribbons 111 and the second ribbons 112 on the end cells 101. During connection of the plurality of cell strings 10, the series connection of the plurality of cell strings 10 can be realized simply by welding the first wiring members 131 of two adjacent cell strings 10 along the second direction, thereby improving the manufacturing efficiency of the photovoltaic module.

It may be understood by those skilled in the art that the above embodiments are particular embodiments to implement the present disclosure, and in a practical application, various changes may be made to the form and details without departing from the spirit and scope of the embodiments of the present disclosure. Those skilled in the art may make variations or modifications without departing from the spirit and scope of the embodiments of the present disclosure, therefore, the scope of protection of the embodiments of the present disclosure shall be subject to the scope of protection as defined by the claims.

What is claimed is:

1. A photovoltaic module, comprising:
a plurality of cell strings, at least two first adjacent cell strings of the plurality of cell strings being arranged along a second direction, each respective cell string of the two first adjacent cell strings including a plurality of back-contact cells arranged sequentially along a first direction, and further including first ribbons, at least one first covering film, second ribbons, second covering films and first wiring members;
wherein the respective cell string includes end cells at opposite ends of the respective cell string, and intermediate cells between the end cells;
a respective first ribbon of the first ribbons extends along the first direction and has two ends respectively disposed on two adjacent back-contact cells of the plurality of back-contact cells;
a respective first covering film of the at least one first covering film covers a surface of at least one intermediate cell of the intermediate cells and embeds the first ribbons on the at least one intermediate cell;
a respective first wiring member of the first wiring members is disposed on a respective intermediate cell of the intermediate cells adjacent to a corresponding end cell of the end cells, and on a side of the at least one first covering film away from the plurality of back-contact cells;
the second ribbons are arranged on at least one of the end cells, at least a portion of the second ribbons being arranged on the corresponding end cell and having end portions extending beyond the corresponding end cell and welded to the respective first wiring member;
a respective second covering film of the second covering films is located on a side of the first ribbons and the portion of the second ribbons away from the corresponding end cell, and covers a surface of the corresponding end cell; and
a first end of a first wiring member of the first wiring members of one of the two first adjacent cell strings is electrically connected by welding to a second end of a first wiring member of the first wiring members of the other one of the two first adjacent cell strings.

2. The photovoltaic module according to claim 1, wherein the respective first wiring member includes a first body portion and a first welding portion; and
in a direction perpendicular to the surface of the at least one intermediate cell, a thickness of the first welding portion is less than a thickness of the first body portion, and the first welding portion is configured to weld and connect the respective first wiring member corresponding to one of the two first adjacent cell strings to the respective first wiring member corresponding to the other of the two first adjacent cell strings.

3. The photovoltaic module according to claim 2, wherein the first welding portion of the respective first wiring member corresponding to one of the two first adjacent cell strings is welded to the first welding portion of the respective first wiring member corresponding to the other of the two first adjacent cell strings via the same connecting tab.

4. The photovoltaic module according to claim 2, wherein the first welding portion of the respective first wiring member corresponding to one of the two first adjacent cell strings is directly welded to the first welding portion of the respective first wiring member corresponding to the other of the two first adjacent cell strings.

5. The photovoltaic module according to claim 1, wherein at least two second adjacent cell strings of the plurality of cell strings are arranged along the first direction, and end cells of the two second adjacent cell strings that are not provided with the second ribbons are disposed adjacent to each other.

6. The photovoltaic module according to claim 5, wherein the photovoltaic module further includes third ribbons and a second wiring member, a respective third ribbon of the third ribbons has two ends that are respectively disposed on a surface of a corresponding end cell of one of the two second adjacent cell strings and on a surface of a corresponding end cell of the other of the two second adjacent cell strings;
the second wiring member is disposed on the respective intermediate cell adjacent to the corresponding end cell, and on a side of the at least one first covering film away from the plurality of back-contact cells; and
end portions of the third ribbons are welded to the same corresponding second wiring member.

7. The photovoltaic module according to claim 6, wherein the respective second covering film is further located on a side of a respective third ribbon of the third ribbons away from the corresponding end cell.

8. The photovoltaic module according to claim 1, further comprising an isolation film located between the first wiring members and the at least one first covering film.

9. The photovoltaic module according to claim 8, wherein a surface of the isolation film facing the at least one first covering film is provided with an adhesive layer.

10. The photovoltaic module according to claim 8, wherein a surface of the isolation film facing the first wiring members is provided with an adhesive layer.

11. The photovoltaic module according to claim 8, wherein a melting point of the isolation film is higher than a melting point of the respective first covering film.

12. The photovoltaic module according to claim 8, wherein the isolation film is further located between the second wiring members and the at least one first covering film.

13. The photovoltaic module according to claim 1, wherein in a direction perpendicular to the surface of the at least one intermediate cell, a thickness of the respective first covering film is greater than a height of the respective first ribbon.

14. The photovoltaic module according to claim 1, wherein in a direction perpendicular to the surface of the corresponding end cell, a thickness of the respective second covering film is greater than a height of the respective first ribbon.

15. The photovoltaic module according to claim 1, wherein in a direction perpendicular to the surface of the corresponding end cell, a thickness of the respective second covering film is greater than the height of the respective second ribbon.

16. The photovoltaic module according to claim 1, wherein the at least one first covering film is a single integrated first covering film and covers the surface of the at least one intermediate cell.

17. The photovoltaic module according to claim 1, wherein a melting point of the respective first covering film is higher than a melting point of the respective second covering film.

18. The photovoltaic module according to claim 1, wherein the respective intermediate cell is individually covered by the respective first covering film.

19. The photovoltaic module according to claim 18, wherein a size of the respective second covering film is greater than or equal to a size of a respective back-contact cell of the plurality of back-contact cells, the size refers to dimension including the width along the first direction and the width along the second direction of both the respective second covering film and the respective back-contact cell.

20. The photovoltaic module according to claim 1, wherein in the second direction, a width of the respective first covering film is greater than or equal to a width of a respective back-contact cell of the plurality of back-contact cells.
